(19) United States
(12) Patent Application Publication
(10) Pub. No.: US 2018/0322231 A1
(43) Pub. Date: Nov. 8, 2018

(54) INTERIOR MAGNET MACHINE DESIGN WITH LOW CORE LOSSES

(71) Applicant: Faraday&Future Inc., Gardena, CA (US)

(72) Inventors: Mengwei Li Campbell, Torrance, CA (US); Jie Dang, Shenzhen (CN)

(73) Assignee: Faraday&Future Inc., Gardena, CA (US)

(21) Appl. No.: 15/772,041

(22) PCT Filed: Oct. 27, 2016
(86) PCT No.: PCT/US2016/059184

§ 371 Date: Apr. 27, 2018

Related U.S. Application Data
(60) Provisional application No. 62/249,157, filed on Oct. 30, 2015.

(51) Int. Cl. G06F 17/50; G01R 33/02; G01R 31/34

(52) U.S. Cl. CPC G06F 17/5018; G06F 2217/12; G01R 31/34; G01R 33/02

(57) ABSTRACT

Methods and apparatus for estimating and minimizing core losses in interior magnet machines are disclosed. Methods can include creating, modifying, or receiving a finite element analysis (FEA) model to represent at least one portion of an motor in a computer system, placing at least one coil at a first location within the rotor iron or stator iron of the motor in the FEA model, calculating a time-domain flux density B of the at least one coil, converting the calculated flux density function to a frequency-domain spectrum, receiving material core loss parameters for at least some frequencies indicated by the frequency-domain spectrum, and determining a core loss of the at least one portion of an electric motor by a weighted combination of the material core loss parameters. Coils may be placed manually by a user through a user interface, or may be placed automatically.

### BACKGROUND OF THE INVENTION

### Field of the Invention

This disclosure relates to methods, systems, and apparatus for minimizing core losses in a motor, and more particularly, to methods for accurately estimating core losses in an interior permanent magnet (IPM) electric motor in a finite element analysis (FEA) simulation.

### Description of the Related Art

Core loss is a significant factor in determining the efficiency of electric motors. Potential electric motor designs are often evaluated using FEA simulations before prototypes are built. Some existing FEA simulation tools contain features providing core loss estimation in connection with IPM motor designs. However, these core loss estimations are generally inaccurate and currently available simulation software does not allow for customization, adjustment, or improvement of the core loss estimation method by users.

### SUMMARY OF THE INVENTION

The systems and methods of this disclosure each have several innovative aspects, no single one of which is solely responsible for its desirable attributes. Without limiting the scope as expressed by the claims that follow, its more prominent features will now be discussed briefly.

In one embodiment, a method of estimating core loss in an electric motor using a FEA simulation is described. The method may include creating, modifying, or receiving a FEA model to represent at least one portion of an electric motor in a computer system. The computer system may include a user interface and a processing circuit configured for FEA simulation. The electric motor may include at least one rotor capable of rotation about a rotational axis and a stator with at least one pole pair disposed radially about the rotational axis of the rotor. The method may further include placing, with the user interface, at least one coil at a first location within the rotor iron or stator iron of the motor in the FEA model. The coil may include a wire loop. The method may also include calculating a time-domain flux density B of the at least one coil as a function of time, converting the calculated flux density function to a frequency-domain spectrum, receiving material core loss parameters for at least some frequencies indicated by the frequency-domain spectrum, and determining a core loss of the at least one portion of an electric motor by a weighted combination of the received material core loss parameters according to the relative magnitudes of the peaks in the discrete frequency-domain spectrum.

In another embodiment, an apparatus for estimating core loss in an electric motor using a FEA simulation is described. The apparatus may include means for creating, modifying, or receiving a FEA model to represent at least one portion of an electric motor in a computer system. The computer system may include a user face and a processing circuit configured for FEA simulation. The electric motor may include at least one rotor capable of rotation about a rotational axis and a stator with at least one pole pair disposed radially about the rotational axis of the rotor. The apparatus may further include means for placing at least one coil at a first location within the rotor iron or stator iron of the motor in the FEA model. The coil may include a wire loop. The apparatus may also include means for calculating a time-domain flux density B of the at least one coil as a function of time, means for converting the calculated flux density function to a frequency-domain spectrum, means for receiving material core loss parameters for at least some frequencies indicated by the frequency-domain spectrum, and means for determining a core loss of the at least one portion of an electric motor by a weighted combination of the received material core loss parameters according to the relative magnitudes of the peaks in the discrete frequency-domain spectrum.

In another embodiment, a computer program product for processing data for a program configured to estimate core loss in an electric motor using a FEA simulation is described. The computer program product may include a non-transitory computer-readable medium having code stored thereon. The code may cause processing circuitry to enable a user to create, modify, or receive a FEA model to represent at least one portion of an electric motor in a computer system. The computer system may include a user interface and a processing circuit configured for FEA simulation. The electric motor may include at least one rotor capable of rotation about a rotational axis and a stator with at least one pole pair disposed radially about the rotational axis of the rotor. The code may further cause processing circuitry to enable placement, with the user interface, of at least one coil at a first location within the iron rotor or stator iron of the motor in the FEA model. The coil may include a wire loop. The code may also cause processing circuitry to calculate a time-domain flux density B of the at least one coil as a function of time, convert the calculated flux density function to a frequency-domain spectrum, receive material core loss parameters for at least some frequencies indicated by the frequency-domain spectrum, and determine a core loss of the at least one portion of an electric motor by a weighted combination of the received material core loss parameters according to the relative magnitudes of the peaks in the discrete frequency-domain spectrum.

### BRIEF DESCRIPTION OF THE DRAWINGS

The above-mentioned aspects, as well as other features, aspects, and advantages of the present technology will now be described in connection with various implementations, with reference to the accompanying drawings. The illustrated implementations are merely examples and are not intended to be limiting. Throughout the drawings, similar symbols typically identify similar components, unless context dictates otherwise.

FIG. 1 is a block diagram illustrating an example flowchart according to one embodiment of a method for estimating core loss in an electric motor.

FIG. 2 depicts an example motor core loss parameter in accordance with an exemplary embodiment.

FIG. 3 depicts a portion of a two-dimensional FEA simulation model of an IPM synchronous motor in accordance with an exemplary embodiment.

FIG. 4A depicts an exemplary process by which a coil may be placed within a FEA simulation model of an IPM synchronous motor by means of a user interface in accordance with an exemplary embodiment.

FIG. 4B depicts an exemplary process by which a coil may be defined within a FEA simulation model of an IPM synchronous motor by means of a user interface in accordance with an exemplary embodiment.

FIG. 5 depicts a two-dimensional FEA model of an IPM synchronous motor with an exemplary configuration of multiple coils in accordance with an exemplary embodiment.

FIG. 6 is a graph depicting an exemplary flux linkage waveform output of a FEA simulation in a user interface in accordance with an exemplary embodiment.

FIG. 7A is a graph depicting an example flux linkage waveform output of a FEA simulation in accordance with an exemplary embodiment.

FIG. 7B is a graph depicting an example frequency-domain spectrum corresponding to the example flux linkage waveform output depicted in FIG. 7A in accordance with an exemplary embodiment.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system that can be configured to execute finite element analysis (FEA) simulation.

In general, this disclosure is related to a technique for minimizing core losses in interior permanent magnet (IPM) electric motors. Efficiency is one of the most important aspects of electric vehicle motor design. Increased motor efficiency results in the extension of electric vehicle range, the distance a vehicle can travel on a single charge of its battery or batteries. Motor efficiency in electric motors is typically calculated using the formula:

$${η}_{m} = \frac{{P}_{out}}{{P}_{in}} = \frac{{P}_{in} - {P}_{loss}}{{P}_{in}}$$

where ηₘ denotes the motor efficiency, Pᵢₙ denotes the input electrical power, Pₒᵤₜ denotes the output mechanical power, and Pₗₒₛₛ denotes the motor power loss. Thus, a reliable estimate of Pₗₒₛₛ is required in order to effectively calculate a motor efficiency map for a proposed motor design.

The total power loss of an operating motor may come from multiple types of power loss. In the case of an IPM electric motor, the motor losses to be calculated are copper loss and core loss. Copper loss is a result of resistance in the copper wire that makes up the windings of the electric motor. Copper loss is relatively easy to estimate accurately because it may be calculated from only the current and resistance of the windings, and the current and resistance are easy to determine.

However, core loss is a more complex function of many variables, including flux density B and frequency f of the engine, which are more difficult to measure. Core losses occur whenever a magnetic core is subjected to a changing magnetic field, which occurs throughout the operation of an interior magnet machine, and include hysteresis loss and eddy current losses. Hysteresis losses occur due to the changing of magnetic domain walls within the core as magnetization changes as a result of a changing magnetic field. Eddy current losses occur due to the electric resistance of the core, as a result of the eddy currents created by magnetic induction as the magnetic field changes. Because core losses result from multiple concurrent phenomena, total core loss is frequently calculated using an empirical equation:

P_{core}=Kₕ×f×(Bₘ)²+K_{c}×(f×Bₘ)²+Kₑ×(f×B)^{1.5}

where P_{core} denotes core power loss, f denotes the motor frequency, and B denotes the maximum flux density. Kₕ, K_{c}, and Kₑ are the coefficients of hysteresis loss, classical eddy current loss, and excess eddy current loss, respectively.

In the operation of an electric motor, this equation may be difficult to evaluate because multiple frequencies may be present simultaneously. The spatial distribution of magnetic flux may increase the difficulty of estimation as well, because the maximum flux density Bₘ may be different in various parts of a motor. The parts of the motor with higher flux density usually have higher core losses, while areas with lower flux density contribute less to the overall core loss. To improve the accuracy of core loss estimation, a new method is proposed which is able to deal with the non-uniform spatial distribution of magnetic flux within an electric motor and calculate individual core losses for smaller parts of a machine.

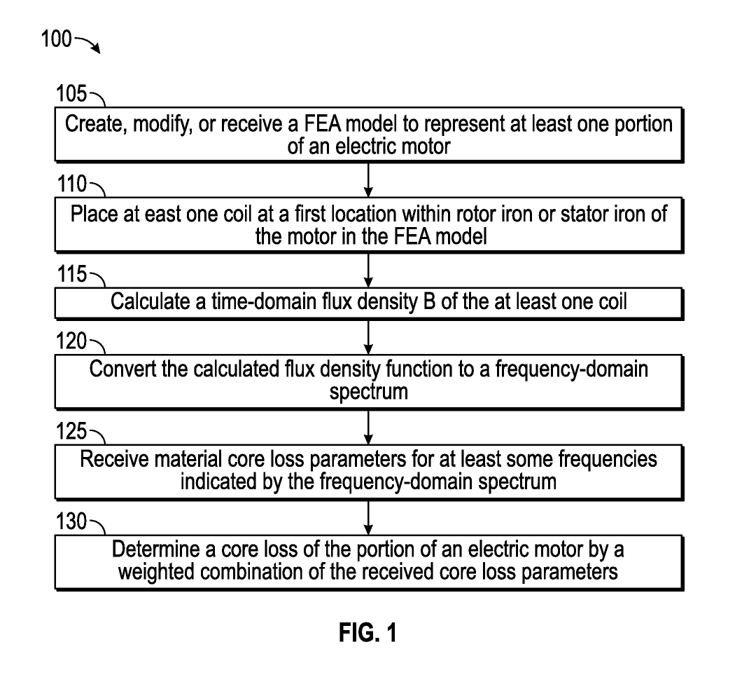

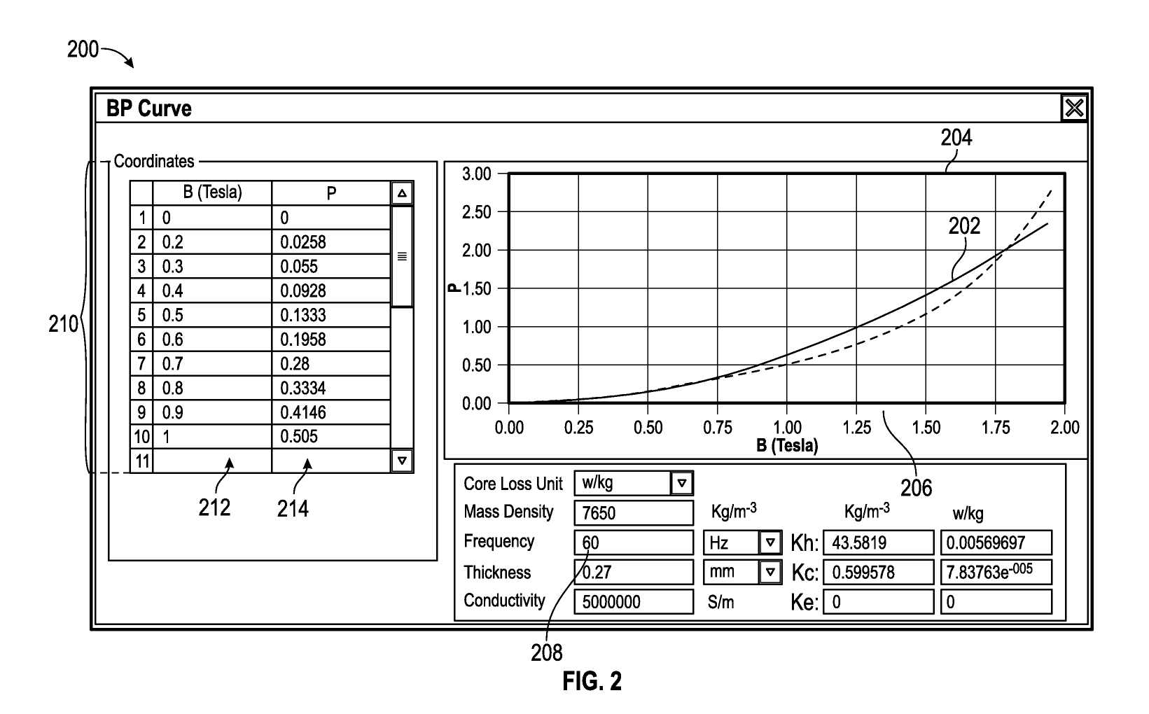

FIG. 1 is a flowchart depicting an exemplary method 100 for estimating core loss in an electric motor using a FEA simulation. In some aspects, the method 100 may be performed with a computer system having a user interface illustrated, for example in FIGS. 2, 4A, 4B, 5, and 6. In various embodiments, the steps of the exemplary method described may be performed individually by user control, or any number of the steps may be included in an automatic process for core loss estimation.

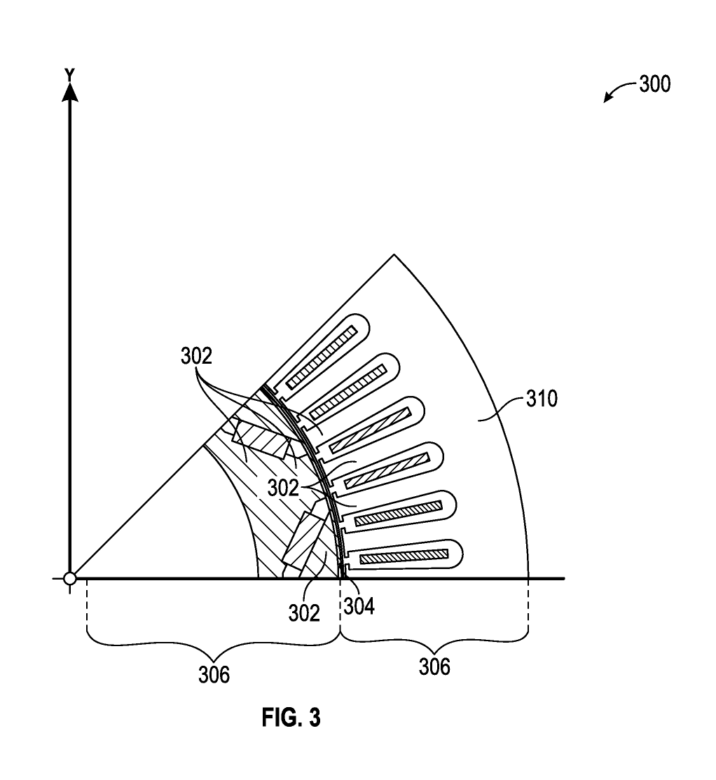

As shown, the method 100 may begin with block 105, where a FEA model is created, modified, or received to represent at least one portion of an electric motor in a computer system. The computer system may comprise a user interface and a processing circuit configured for FEA simulation. In some embodiments, the FEA model may be a model of at least a portion of an IPM synchronous motor, as described with reference to FIGS. 3, 4A, 4B, and 5 below. The FEA model may be compatible with a software environment capable of performing electromagnetic FEA simulation, such as ANSYS/Ansoft Maxwell motor design software or any other FEA simulation product.

After creating, modifying, or receiving a FEA model, the method 100 may continue to block 110, where a user places at least one coil at a first location within the rotor iron or stator iron of the motor in the FEA model. In some embodiments, the user may place multiple coils at various locations within the FEA model, for example, in both the rotor iron and the stator iron. The locations of the coils may be chosen based on a division of the FEA model into segments of known weight, with one coil across each segment, to facilitate the calculation of a total motor core loss from received core loss parameters indicating core loss per unit weight.

In some embodiments, a user may prefer to increase the number of coils in the FEA model so as to accurately and completely investigate the magnetic flux distribution throughout a motor model. However, a user may prefer to limit the number of coils so as to avoid making an overly complex model that takes an undesirably long time to run a simulation due to large data processing requirements. Typically, an arrangement of coils may include 1 to 20 coils. Often a desirable arrangement will be limited to approximately 5 to 10 coils. In various embodiments, any number of coils may be used, depending on the type of motor being simulated and the data processing capability of the computer system used. It is expected that a person having ordinary skill in the art will be able to determine an optimal number and arrangement of coils relatively quickly with minimal experimentation necessary.

After placing at least one coil, the method 100 may continue to block 115, where a time-domain flux density B of the at least one coil is calculated. In some embodiments, calculation of the time-domain flux density may be done automatically by the FEA simulation software. In other embodiments, the time-domain flux density may be calculated from an output including a time-domain flux linkage of the coil, a time-domain induced current or EMF in the coil, and/or any other electromagnetic property of the coil that may be produced as an output of the FEA simulation. Calculation of a flux density from any such possible outputs may be performed based on well-known electromagnetic principles that will be readily apparent to a person having ordinary skill in the art. For example, an output comprising a flux linkage λ may be converted to a flux density B using the formula:

$$B = \frac{λ}{A}$$

where A is the area of the coil.

After calculation of the time-domain flux density B of the at least one coil, the method 100 may continue to block 120, where the calculated flux density function is converted to a frequency-domain spectrum. The frequency-domain spectrum produced by conversion from the time-domain function may have peaks at the frequencies present in the time-domain function. In some aspects, these indicated frequencies may include a fundamental electric frequency, which may be related to the fundamental motor rotation frequency and the number of pole pairs in the stator. The indicated frequencies may further include harmonic frequencies of the fundamental electric frequency which may also be present in the flux density function. Conversion to a frequency-domain spectrum may be performed, for example, by various types of Fourier analysis, such as a discrete Fourier transform, fast Fourier transform, or the like.

After the flux density function is converted to a frequency-domain spectrum, the method 100 may proceed to block 125, where a user may receive material core loss parameters for at least some of the frequencies indicated by the frequency-domain spectrum. In some embodiments, the material core loss parameters may be specific to a particular motor construction material and frequency. Motor core loss parameters may quantify core loss per unit weight as a function of flux density B. Motor core loss parameters may include B-P curves, described below with reference to FIG. 2, as well as any other parameters related to the magnetic motor core loss associated with changing magnetic fields with a motor.

Once material core loss parameters are received, the method 100 may proceed to block 130, where a core loss of the portion of an electric motor is determined by a weighted combination of the received core loss parameters. Weighting of the received core loss parameters may be performed in proportion to the relative amplitudes of the frequency peaks in the frequency-domain spectrum. In some embodiments where fewer than all of the frequencies indicated in the frequency-domain spectrum are included in the weighted combination, the included frequencies may be selected by the user based on the significance of contribution to overall motor core losses, availability of core loss parameters, or any other criteria the user may consider. The weighted combination of material core loss parameters may allow the user to compute an estimated total core loss value for any portion of an electric motor, or for the entire motor, by adding together the calculated core losses for some or all segments of the FEA model described above with reference to block 110. In some embodiments, an estimated total core loss may be used to modify, adjust, improve, redesign, or otherwise change the design of an electric motor so as to create a motor with lower core losses and greater efficiency.

FIG. 2 depicts a “B-P” curve 202 as it may be represented in an application window 200 of a motor design software product. A B-P 202 curve may be used to calculate the core loss coefficients Kₕ, K_{c}, and Kₑ for use in the core loss equation above. In the B-P curve, core loss is represented on the Y-axis 204 as a function of maximum flux density, represented on the X-axis 206. In this example, the core loss is given as a core loss per unit weight of motor construction material, in units of W/kg. A B-P curve may be specific to a particular material and frequency 208, and may be generated from an experimentally measured data set 210. In some aspects, a data set for a B-P curve may comprise a list of experimentally applied maximum flux densities 212 at a particular frequency 208, together with the corresponding measured actual motor core losses 214. For purposes of design and simulation, B-P curves may be obtained from manufacturers of the motor construction materials, or from material data sheets.

Given a B-P curve for a particular frequency, core loss coefficients Kₕ, K_{c}, and Kₑ may be calculated by minimizing the formula:

err(kₕ,kₕ,kₕ)=[Pᵥ−(Kₕ·f·(Bₘ)²+K_{c}·(f·Bₘ)²+Kₑ·(f·Bₘ)^{1.5})]=min

In this manner, the core loss coefficients may be determined empirically from an experimentally obtained set of B-P data points. However, most motor material datasheets do not contain high-frequency B-P curves. Materials suitable for electric motor construction are frequently used primarily for electric utility transformers. Because the fundamental utility frequency of electric power systems is typically 50 Hz or 60 Hz, manufacturers often provide B-P curves for only these frequencies.

In contrast, an electric traction motor may work at much higher frequencies. Rated motor speeds may be between 3,000 rpm and 5,000 rpm, so normal fundamental frequencies may be between 250 Hz and 700 Hz. The corresponding harmonic frequencies may be between 1.25 kHz and 4 kHz. For high-speed operation up to 15,000 rpm, the fundamental frequency may be as high as 2 kHz, with corresponding harmonic frequencies up to 12 kHz. Thus, for an accurate core loss estimation, the B-P curves of the frequencies between 50 Hz and 10 kHz should be provided. These curves must be determined experimentally, preferably by the motor construction material manufacturers. If B-P curves can be obtained for a relatively large number of the frequencies within the required range of frequencies, direct linear interpolation may be used instead of calculating core loss coefficients Kₕ, K_{c}, and Kₑ.

FIG. 3 depicts an exemplary portion 300 of a two-dimensional FEA model of an IPM synchronous motor in accordance with an exemplary embodiment. In this exemplary embodiment, the model portion 300 is shown as created, received, or modified, without the additional placement of a coil or coils for magnetic flux distribution analysis. Higher core losses may be closely associated with the areas of highest flux density within a motor. Typically, the areas 302 close to the air gap 304 between the rotor 306 and stator 308 have the highest flux density. Other areas 310 further from the air gap 304 may have lower flux densities, and accordingly contribute less to motor core loss. Thus, a reliable estimation method for core losses should be able to account for this spatial distribution of magnetic flux and calculate individual core loss estimates for each region.

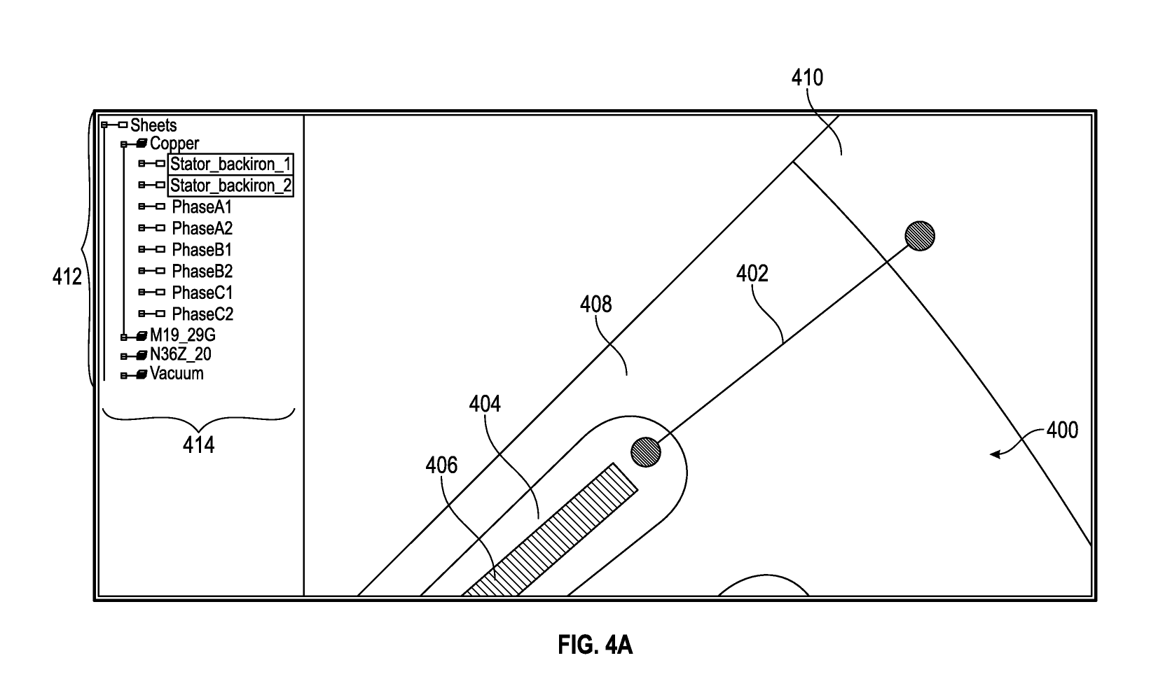

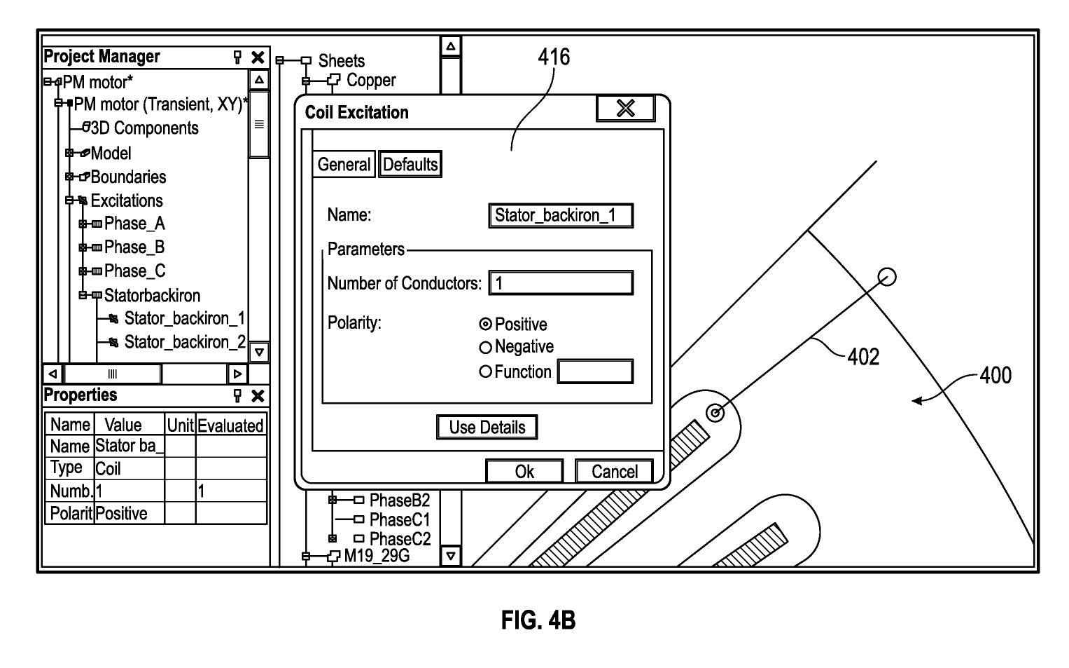

FIGS. 4A and 4B depict an exemplary process by which a coil 402 may be added to a FEA model 400 of an IPM synchronous motor by means of a user interface in accordance with an exemplary embodiment.

FIG. 4A depicts an exemplary first placing step of placing the boundaries of a coil 402 within the FEA model 400. In some embodiments, a coil 402 may be placed, for example, with one boundary in the gap 404 between a stator tooth 406 and the stator iron 408, and its other boundary in the space 410 outside the stator, thus spanning the width of the stator back iron. Having been placed in the FEA simulation software, the added coil 402 may also appear in a list 412 of modeled objects within a pane 414 or similar area of a FEA simulation user interface.

FIG. 4B depicts an exemplary second definition step following the exemplary first placing step shown in FIG. 4A. In some embodiments, after a coil 402 has been placed in a FEA model 400, any properties of the coil or coils, such as number of turns, polarity, output functions, or any other definable quality of a modeled coil, may be defined in a window 416 of the user interface. The coil or coils may comprise any malleable conductive material capable of being formed into a wire. For example, in some embodiments the coil material may be copper or other metal commonly used for fabrication of wires or circuits. Each coil may comprise a single turn of wire, and the wire may be of a small diameter. It will be readily apparent that using a one-turn coil with a small diameter wire will minimize any alteration of the original magnetic flux distribution of a motor due to the presence of the coil or coils.

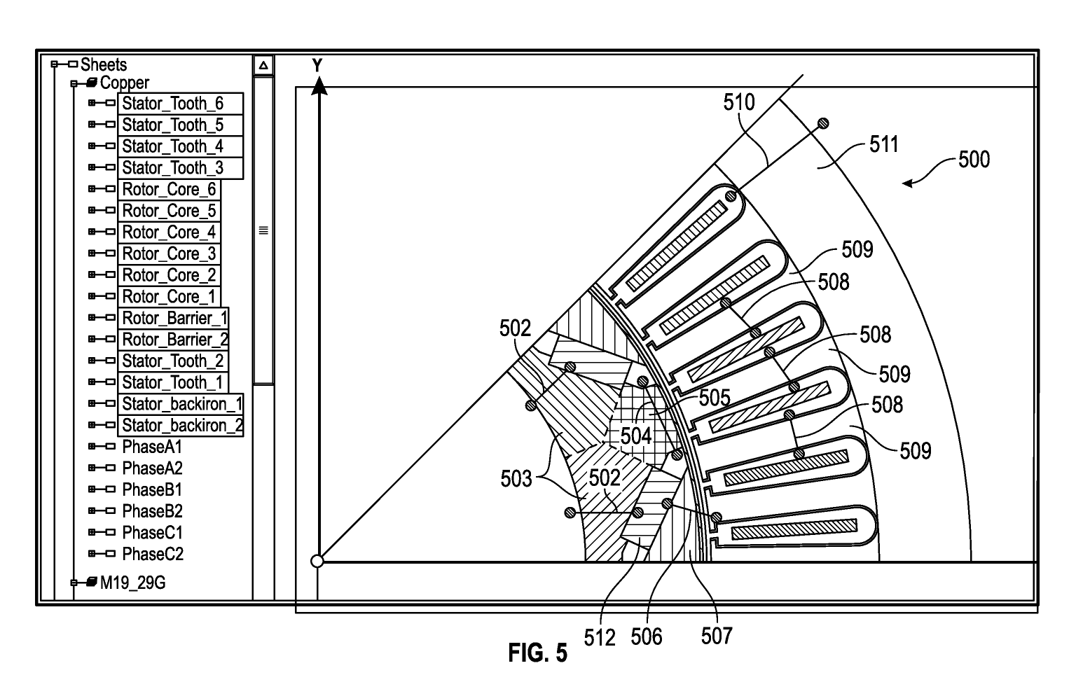

FIG. 5 depicts an exemplary portion 500 of a two-dimensional FEA model of an IPM synchronous motor with an exemplary configuration of multiple coils and model segments in accordance with an illustrative embodiment. In some embodiments, one or more coils 502, 504, 506, 508, and/or 510 may be placed within a FEA simulation model to evaluate the flux density at the location of the coils. In some aspects, the coil or coils may comprise wire loops. Generally, a changing flux density within a wire loop results in an induced electromotive force (EMF), which causes a current to flow within the wire loop. Current in a wire loop is easy to measure, which allows for the calculation of the time-domain flux linkage through the loop. The time-domain flux density within the loop may be calculated directly from the time-domain flux linkage and the area of the wire loop. In some embodiments, a particular simulation environment may provide a direct output of a flux linkage or flux density, reducing the required number of calculations after the simulation.

Coil location may be determined based on the expected areas of highest magnetic flux density in a FEA model. In some embodiments, a FEA simulation model may be divided into segments of known weight consistent with coil placement so as to evaluate the magnetic flux density within each segment. For example, in an IPM synchronous motor, coil placement may include coil 502 across segment 503 in the rotor iron between a rotor magnet 512 and the rotor core, coil 504 across segment 505 at the rotor barrier, coil 506 across segment 507 and the air gap, coil 508 across one or more stator teeth, and/or coil 510 across the stator back-iron. In some embodiments, locations near the air gap may be emphasized. It will be readily apparent to one having ordinary skill in the art that a coil or coils can be placed at any one or combination of these locations, as well as in any other location within the FEA model where significant magnetic flux may be present.

In an IPM synchronous motor, the flux path may travel from a magnet through the rotor core, across the air gap, through a stator tooth to the stator back-iron, and eventually through a stator tooth back to the magnet. During an electromagnetic FEA simulation of an IPM synchronous motor, the flux linkage through each region of the motor remains constant, but may reverse direction or change in magnitude. Therefore, the coils may be placed across the flux path, rather than parallel to the flux path, in order to accurately detect the change in flux density over time.

In some embodiments, a FEA simulation product will not allow the placement of coils within a material, such as a magnet, rotor iron, or stator iron. This may cause difficulty for placement of some coils, such as, for example, coils 502 or 506 as depicted in FIG. 5, where a user may desire to place at least one boundary in a location where the FEA model does not contain a suitable air gap. In some embodiments, this problem may be solved by adjusting the model to contain a very small air gap in which to place the coil. For example, such a gap may be as narrow as 0.1 millimeters so as to minimize any effect on the magnetic flux distribution of the motor. In other embodiments, the same problem may be solved by separating a narrow portion of the rotor iron or stator iron in the location of the desired coil placement, and defining the separated narrow portion as the trivial coil.

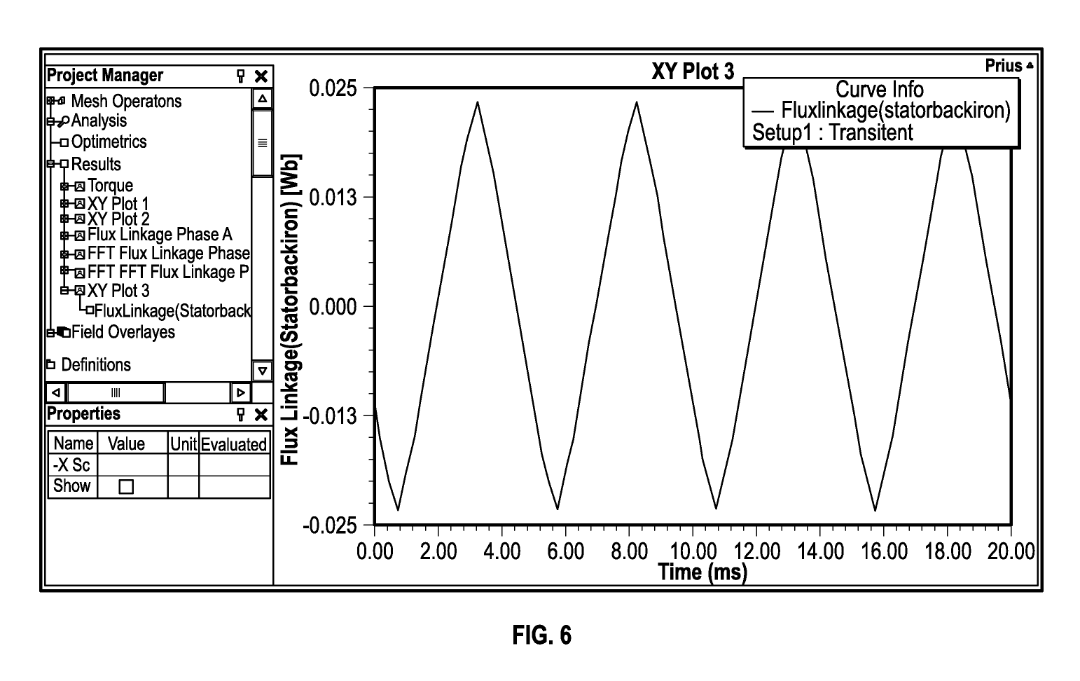

FIG. 6 is a graph depicting a possible flux linkage waveform simulation output in accordance with an exemplary embodiment. The flux waveform received from a FEA simulation may exhibit cyclical and/or sinusoidal characteristics. However, the waveform may not be perfectly sinusoidal, and may instead comprise the superposition of multiple waveforms of various frequencies and amplitudes. Fourier analysis may be used to break down such a waveform into simpler constituent functions of various frequencies. To determine all frequencies present in the time-domain flux waveform, Fourier analysis may transform the flux waveform from a time-domain function to a frequency-domain spectrum.

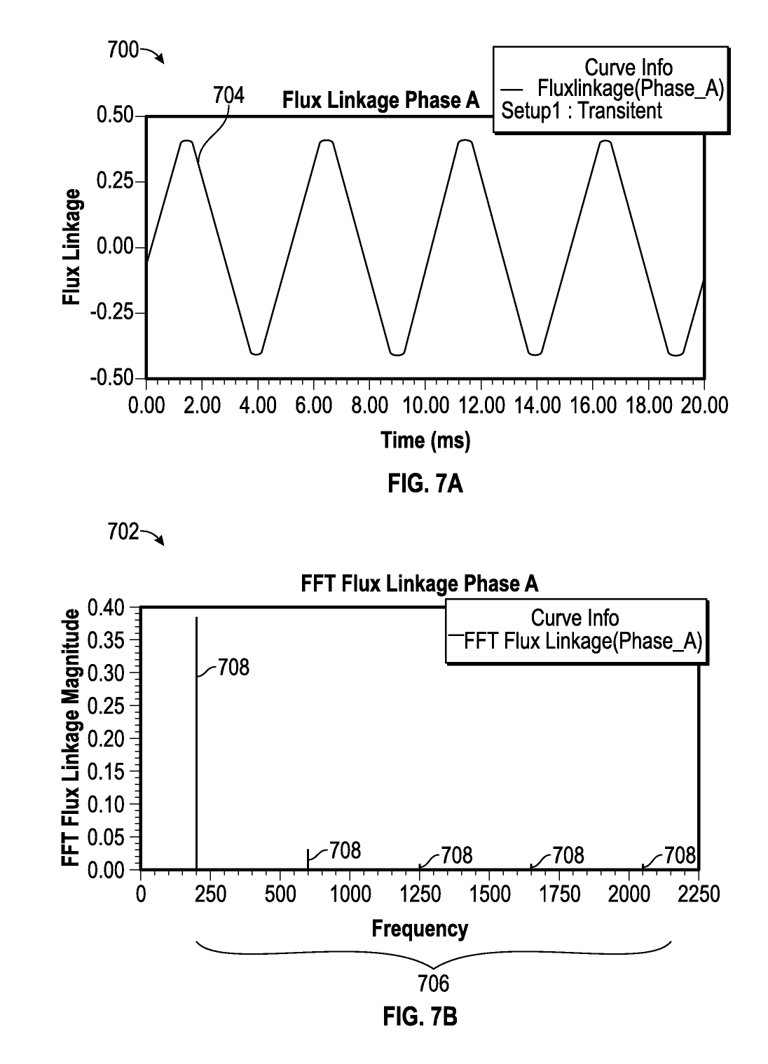

FIG. 7 depicts an example process by which a time-domain flux waveform may be transformed to a corresponding frequency-domain spectrum. FIG. 7A is a graph 700 depicting an example flux waveform 704. FIG. 7B is a graph 702 depicting a corresponding frequency-domain spectrum 706 with peaks 708 indicating the frequencies of oscillation present in the waveform 704 of FIG. 7A. In some embodiments, a time-domain flux waveform 704 may be transformed to a frequency-domain spectrum 706 by calculating the discrete Fourier transform of the time-domain flux waveform function 704. Calculation of the discrete Fourier transform may be accomplished by a fast Fourier transform or by any other appropriate algorithm. As will be readily apparent to one having ordinary skill in the art, the frequency-domain spectrum 706 has peaks 708 at the frequencies present in the time-domain flux waveform. The relative amplitudes of the peaks 708 present in the frequency-domain spectrum indicate the relative amplitudes of the oscillation at each frequency.

Next, the B-P curves for the motor construction material may then be obtained for some or all of the frequencies having peaks in the frequency-domain spectrum. In some embodiments, at least one frequency indicated by the frequency-domain spectrum may be omitted. Preferably, any frequencies which are omitted will be high frequencies having very low peaks in the frequency-domain spectrum, as such frequencies are likely to have relatively small contributions to the total core loss of a motor. The B-P curves may then be combined in a weighted combination and used, along with the weights of the segments of the FEA model, to determine a final estimate of the core loss in the portion of a motor being studied. The weighting of the combination of B-P curves may be determined based on the relative amplitudes of the peaks in the frequency-domain spectrum.

In some embodiments, some or all of the steps described above may be implemented as automatic features of a FEA simulation software product. For example, in some embodiments the segmentation of the electric motor and/or the placement of coils at the most relevant locations within the electric motor or segment of an electric motor may be predetermined, so as to allow users to take advantage of the enhanced estimation accuracy described herein without having to carry out all steps manually. Moreover, a FEA simulation software product may include an automatic coil placement and core loss calculation process, while also allowing users to change or modify the coil placement to provide additional customized flexibility.

It is noted that the examples may be described as a process. Although the operations may be described as a sequential process, many of the operations can be performed in parallel, or concurrently, and the process can be repeated. In addition, the order of the operations may be rearranged. A process is terminated when its operations are completed. A process may correspond to a method, a function, a procedure, a subroutine, a subprogram, etc. When a process corresponds to a software function, its termination corresponds to a return of the function to the calling function or the main function.

The previous description of the disclosed implementations is provided to enable any person skilled in the art to make or use the present disclosed process and system. Various modifications to these implementations will be readily apparent to those skilled in the art, and the generic principles defined herein may be applied to other implementations without departing from the spirit or scope of the disclosed process and system. Thus, the present disclosed process and system is not intended to be limited to the implementations shown herein but is to be accorded the widest scope consistent with the principles and novel features disclosed herein.

What is claimed is:

1. A method of estimating core loss in an electric motor using a finite element analysis (FEA) simulation, comprising the acts of:
creating, modifying, or receiving a FEA model to represent at least one portion of an electric motor in a computer system, the computer system comprising a user interface and a processing circuit configured for FEA simulations, the electric motor comprising at least one rotor capable of rotation about a rotational axis and a stator having at least one pole pair disposed radially about the rotational axis of the rotor;
placing, with the user interface, at least one coil at a first location around at least one portion of the rotor iron or stator iron of the motor in the FEA model, the coil comprising a wire loop;
calculating a time-domain flux density B of the at least one coil as a function of time;
converting the calculated flux density function to a frequency-domain spectrum;
receiving material core loss parameters for at least some frequencies indicated by the frequency-domain spectrum; and
determining a core loss of the at least one portion of an electric motor by a weighted combination of the received material core loss parameters according to the relative magnitudes of the peaks in the discrete frequency-domain spectrum.

2. The method of claim 1, further comprising the act of modifying, adjusting, or redesigning a FEA model based on the estimated core loss so as to minimize core loss.

3. The method of claim 2, further comprising manufacturing an electric motor based on the modified, adjusted, or redesigned FEA model.

4. The method of claim 1, wherein the at least one portion of an electric motor comprises at least one portion of the at least one rotor and at least one portion of the stator.

5. The method of claim 1, further comprising executing a time-stepped FEA simulation of the FEA model.

6. The method of claim 1, further comprising receiving an output from the processing circuit configured for FEA simulations, the output comprising a flux linkage or flux density of the at least one coil as a function of time.

7. The method of claim 1, wherein converting the calculated flux density function to a frequency-domain spectrum comprises computing a discrete Fourier transform (DFT) of the time-domain flux density function.

8. The method of claim 1, wherein the material core loss parameters comprise B-P curves.

9. An apparatus for estimating core loss in an electric motor using a finite element analysis (FEA) simulation, the apparatus comprising:
means for creating, modifying, or receiving a FEA model to represent at least one portion of an electric motor in a computer system, the computer system comprising a user interface and a processing circuit configured for FEA simulations, the electric motor comprising at least one rotor capable of rotation about a rotational axis and a stator having at least one pole pair disposed radially about the rotational axis of the rotor;
means for placing at least one coil at a first location within the rotor iron or stator iron of the motor in the FEA model, the coil comprising a wire loop;
means for calculating a time-domain flux density B of the at least one coil as a function of time;
means for converting the calculated flux density function to a frequency-domain spectrum;
means for receiving material core loss parameters for at least some frequencies indicated by the frequency-domain spectrum; and
means for determining a core loss of the at least one portion of an electric motor by a weighted combination of the received material core loss parameters according to the relative magnitudes of the peaks in the discrete frequency-domain spectrum.

10. The apparatus of claim 9, wherein the at least one portion of an electric motor comprises at least one portion of the at least one rotor and at least one portion of the stator.

11. The apparatus of claim 9, further comprising means for executing a time-stepped FEA simulation of the FEA model.

12. The apparatus of claim 9, further comprising means for receiving an output from the processing circuit configured for FEA simulations, the output comprising a flux linkage or flux density of the at least one trivial coil as a function of time.

13. The apparatus of claim 9, wherein converting the calculated flux density function to a frequency-domain spectrum comprises computing a discrete Fourier transform (DFT) of the time-domain flux density function.

14. The apparatus of claim 9, wherein the material core loss parameters comprise B-P curves.

15. A computer program product for processing data for a program configured to estimate core loss in an electric motor using a finite element analysis (FEA) simulation, the computer program product comprising:
a non-transitory computer-readable medium having stored thereon code for causing processing circuitry to:
enable a user to create, modify, or receive a FEA model to represent at least one portion of an electric motor in a computer system, the computer system comprising a user interface and a processing circuit configured for FEA simulations, the electric motor comprising at least one rotor capable of rotation about a rotational axis and a stator having at least one pole pair disposed radially about the rotational axis of the rotor;
enable placement, with the user interface, of at least one coil at a first location within the rotor iron or stator iron of the motor in the FEA model, the coil comprising a wire loop;
calculate a time-domain flux density B of the at least one coil as a function of time;
convert the calculated flux density function to a frequency-domain spectrum;
receive material core loss parameters for at least some frequencies indicated by the frequency-domain spectrum; and
determine a core loss of the at least one portion of an electric motor by a weighted combination of the received material core loss parameters according to the relative magnitudes of the peaks in the discrete frequency-domain spectrum.

16. The computer program product of claim 15, wherein the at least one portion of an electric motor comprises at least one portion of the at least one rotor and at least one portion of the stator.

17. The computer program product of claim 15, wherein the code stored on the non-transitory computer-readable medium further causes processing circuitry to execute a time-stepped FEA simulation of the FEA model.

18. The computer program product of claim 15, wherein the code stored on the non-transitory computer-readable medium further causes processing circuitry to receive an output from the processing circuit configured for FEA simulations, the output comprising a flux linkage or flux density of the at least one trivial coil as a function of time.

19. The computer program product of claim 15, wherein the code for causing processing circuitry to convert the calculated flux density function to a frequency-domain spectrum comprises code for causing processing circuitry to compute a discrete Fourier transform (DFT) of the time-domain flux density function.

20. The computer program product of claim 15, wherein the material core loss parameters comprise B-P curves.
